(19) United States
(12) Patent Application Publication
(10) Pub. No.: US 2024/0223038 A1
(43) Pub. Date: Jul. 4, 2024

(54) COIL SUBSTRATE, MOTOR COIL SUBSTRATE, AND MOTOR

(71) Applicant: IBIDEN CO., LTD., Ogaki (JP)

(72) Inventors: Takahisa HIRASAWA, Ogaki (JP); Takayuki FURUNO, Ogaki (JP)

(73) Assignee: IBIDEN CO., LTD., Ogaki (JP)

(21) Appl. No.: 18/605,882

(22) Filed: Mar. 15, 2024

Related U.S. Application Data
(63) Continuation of application No. PCT/JP2022/033032, filed on Sep. 1, 2022.

(30) Foreign Application Priority Data
Sep. 15, 2021 (JP) 2021-149921

(51) Int. Cl. H02K 3/28; H02K 1/12

(52) U.S. Cl. CPC H02K 3/28; H02K 1/12; H02K 2203/03

(57) ABSTRACT

A coil substrate includes a flexible substrate, and a coil including a first wiring formed on a first surface of the flexible substrate and a second wiring formed on a second surface of the flexible substrate on the opposite side with respect to the first surface. The flexible substrate is formed to be wound around an axis extending in an orthogonal direction orthogonal to a longitudinal direction of the flexible substrate such that the flexible substrate is formed into a cylindrical shape, and the coil is formed such that the first wiring has a first orthogonal part extending along the orthogonal direction, that the second wiring has a second orthogonal part extending along the orthogonal direction, and that at least one of the first orthogonal part and the second orthogonal part has at least one slit formed along the orthogonal direction.

### CROSS-REFERENCE TO RELATED APPLICATIONS

The present application is a continuation of and claims the benefit of priority to International Application No. PCT/JP2022/033032, filed Sep. 1, 2022, which is based upon and claims the benefit of priority to Japanese Application No. 2021-149921, filed Sep. 15, 2021. The entire contents of these applications are incorporated herein by reference.

### BACKGROUND OF THE INVENTION

### Field of the Invention

The present invention relates to a coil substrate, a motor coil substrate formed using the coil substrate, and a motor formed using the motor coil substrate.

### Description of Background Art

Japanese Patent Application Laid-Open Publication No. 2020-61532 describes a coil substrate having a flexible substrate and spiral-shaped wirings formed on both sides of the flexible substrate. The entire contents of this publication are incorporated herein by reference.

### SUMMARY OF THE INVENTION

According to one aspect of the present invention, a coil substrate includes a flexible substrate, and a coil including a first wiring formed on a first surface of the flexible substrate and a second wiring formed on a second surface of the flexible substrate on the opposite side with respect to the first surface. The flexible substrate is formed to be wound around an axis extending in an orthogonal direction orthogonal to a longitudinal direction of the flexible substrate such that the flexible substrate is formed into a cylindrical shape, and the coil is formed such that the first wiring has a first orthogonal part extending along the orthogonal direction, that the second wiring has a second orthogonal part extending along the orthogonal direction, and that at least one of the first orthogonal part and the second orthogonal part has at least one slit formed along the orthogonal direction.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view schematically illustrating a coil substrate of an embodiment.

FIG. 2 is a bottom view schematically illustrating the coil substrate of the embodiment.

FIG. 3 is an enlarged explanatory diagram schematically illustrating a portion of a first orthogonal part.

FIG. 4 is an enlarged explanatory diagram schematically illustrating a portion of a second orthogonal part.

FIG. 5 is a cross-sectional view schematically illustrating a portion of the coil substrate of the embodiment.

FIG. 6 is a perspective view schematically illustrating a motor coil substrate of the embodiment.

FIG. 7 is a cross-sectional view schematically illustrating a motor of the embodiment.

FIG. 8 is a plan view schematically illustrating a coil substrate of a first modified example.

FIG. 9 is a bottom view schematically illustrating the coil substrate of the first modified example.

FIG. 10 is a cross-sectional view schematically illustrating a portion of the coil substrate of the first modified example.

### DETAILED DESCRIPTION OF THE EMBODIMENTS

Embodiments will now be described with reference to the accompanying drawings, wherein like reference numerals designate corresponding or identical elements throughout the various drawings.

### Embodiment

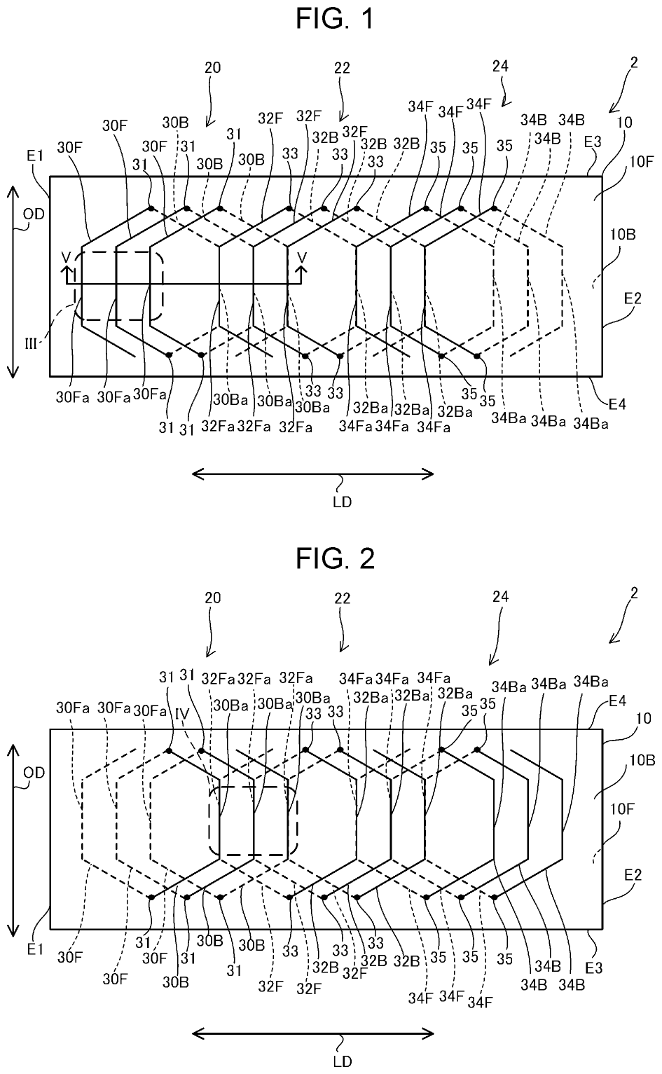

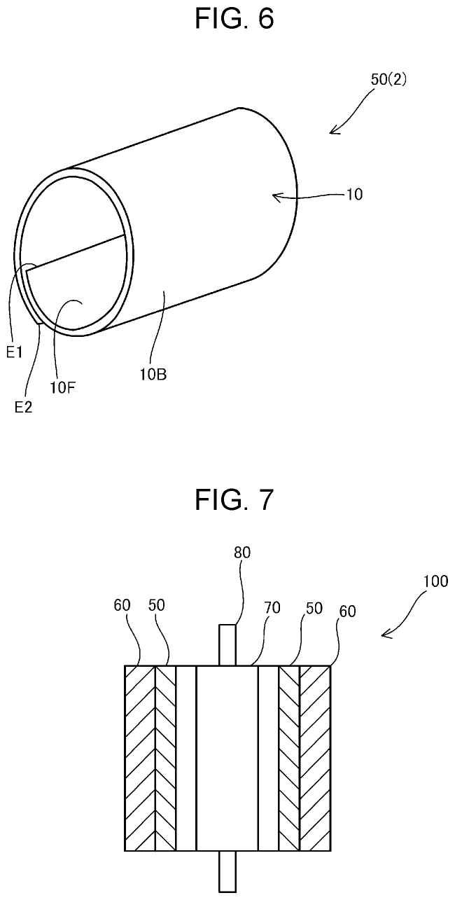

FIG. 1 is a plan view illustrating a coil substrate 2 according to an embodiment of the present invention. FIG. 2 is a bottom view illustrating the coil substrate 2 of the embodiment. The coil substrate 2 has a flexible substrate 10 and three coils (20, 22, 24). The flexible substrate 10 is a resin substrate having a first surface (10F) and a second surface (10B) on the opposite side with respect to the first surface (10F). The flexible substrate 10 is formed using an insulating resin such as polyimide or polyamide. The flexible substrate 10 is flexible. The flexible substrate 10 is formed in a rectangular shape having four sides, first side (E1)-fourth side (E4). The first side (E1) is a short side on one end side of the flexible substrate 10 in a longitudinal direction (arrow (LD) direction in FIG. 1). The second side (E2) is a short side on the other end side in the longitudinal direction. The first side (E1) and the second side (E2) are short sides extending along an orthogonal direction (arrow (OD) direction in FIG. 1) that is orthogonal to the longitudinal direction. The third side (E3) and the fourth side (E4) are long sides extending in the longitudinal direction. As will be described in detail later, when the coil substrate 2 is wound into a substantially cylindrical shape to form a motor coil substrate 50 (see FIG. 6), the first surface (10F) is positioned on an inner peripheral side and the second surface (10B) is positioned on an outer peripheral side.

The coils (20, 22, 24) are formed along the longitudinal direction of the flexible substrate 10. The three coils (20, 22, 24) may respectively form a U phase, a V phase, and a W phase of a three-phase motor. The three coils (20, 22, 24) are formed in this order from the first side (E1) to the second side (E2). In a modified example, the flexible substrate 10 may be provided with fewer than three coils or may be provided with four or more coils.

The coil 20 is formed by that a first wiring (30F) forming a half turn of one turn is formed on the first surface (10F) side, a second wiring (30B) forming the remaining half turn is formed on the second surface (10B) side, and adjacent turns are formed in a staggered manner. In FIGS. 1 and 2, the coil 20 has wirings for three turns. The first wiring (30F) and the second wiring (30B) that form each turn are electrically connected via a via conductor 31 penetrating the flexible substrate 10. The first wiring (30F) has a first orthogonal part (30Fa) extending along the orthogonal direction (see the arrow (OD)). The second wiring (30B) also has a second orthogonal part (30Ba) extending along the orthogonal direction.

Similarly, the coil 22 is formed by that a first wiring (32F) forming a half turn of one turn is formed on the first surface (10F) side, a second wiring (32B) forming the remaining half turn is formed on the second surface (10B) side, and adjacent turns are formed in a staggered manner. The coil 22 has wirings for three turns. The first wiring (32F) and the second wiring (32B) that form each turn are electrically connected via a via conductor 33. The first wiring (32F) has a first orthogonal part (32Fa) extending along the orthogonal direction (see the arrow (OD)). The second wiring (32B) also has a second orthogonal part (32Ba) extending along the orthogonal direction.

The coil 24 is formed by that a first wiring (34F) forming a half turn of one turn is formed on the first surface (10F) side, a second wiring (34B) forming the remaining half turn is formed on the second surface (10B) side, and adjacent turns are formed in a staggered manner. The coil 24 has wirings for three turns. The first wiring (34F) and the second wiring (34B) that form each turn are electrically connected via a via conductor 35. The first wiring (34F) has a first orthogonal part (34Fa) extending along the orthogonal direction (see the arrow (OD)). The second wiring (34B) also has a second orthogonal part (34Ba) extending along the orthogonal direction.

As illustrated in FIGS. 1 and 2, the second orthogonal part (30Ba) of the second wiring (30B) forming the coil 20 overlaps the first orthogonal part (32Fa) of the first wiring (32F) forming the adjacent coil 22 via the flexible substrate 10.

The second orthogonal part (32Ba) of the second wiring (32B) forming the coil 22 overlaps the first orthogonal part (34Fa) of the first wiring (34F) forming the adjacent coil 24 via the flexible substrate 10. The arrangement of the coils (20, 22, 24) in FIGS. 1 and 2 is merely an example. In other modified examples, it is also possible that the second orthogonal part (30Ba) of the second wiring (30B) forming the coil 20 does not overlap with the first orthogonal part (32Fa) of the first wiring (32F) forming the immediately adjacent coil 22 as long as it overlaps with the first orthogonal part of the first wiring forming another coil (for example, the first orthogonal part of the first wiring of a third adjacent coil). Similarly, it is also possible that the second orthogonal part (32Ba) of the second wiring (32B) forming the coil 22 also does not overlap with the first orthogonal part (34Fa) of the first wiring (34F) forming the immediately adjacent coil 24 as long as it overlaps with the first orthogonal part of the first wiring forming another coil (for example, the first orthogonal part of the first wiring of the third adjacent coil).

Further, although not illustrated, the first surface (10F) and the first wirings (30F, 32F, 34F) are covered with a resin insulation layer. Similarly, the second surface (10B) and the second wirings (30B, 32B, 34B) are covered with a resin insulation layer.

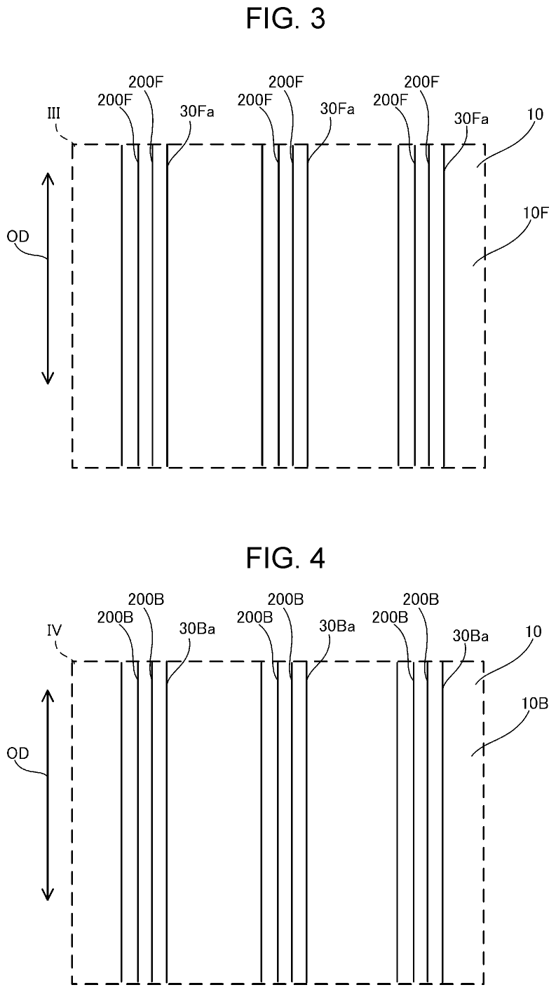

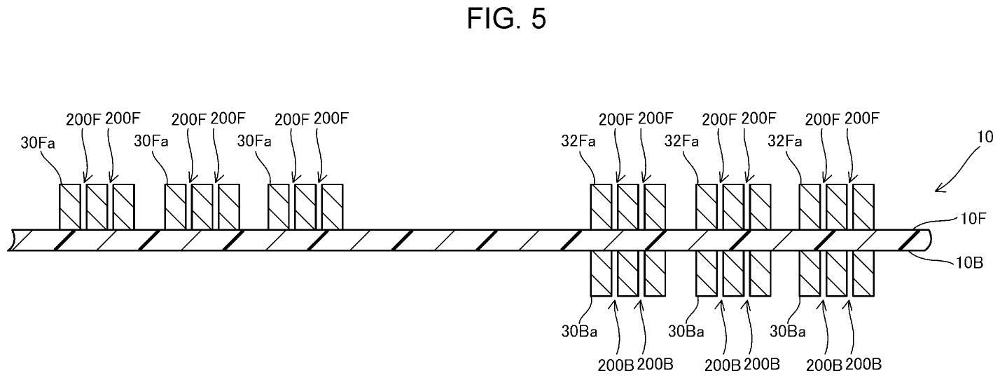

FIG. 3 is an enlarged explanatory diagram illustrating a portion of the first orthogonal part (30Fa) of the first wiring (30F) described. FIG. 3 is an enlarged view of a portion (III) in FIG. 1. FIG. 4 is an enlarged explanatory diagram illustrating a portion of the second orthogonal part (30Ba) of the second wiring (30B) described. FIG. 4 is an enlarged view of a portion (IV) in FIG. 2. FIG. 5 is a cross-sectional view between V-V in FIG. 1.

As illustrated in FIGS. 3 and 5, two slits (200F) are formed in the first orthogonal part (30Fa) along the orthogonal direction. The slits (200F) are formed over an entire length of the first orthogonal part (30Fa). As illustrated in FIG. 5, the slits (200F) are formed at a depth reaching the first surface (10F) from an upper surface of the first orthogonal part (30Fa). As illustrated in FIG. 5, similar to the first orthogonal part (30Fa), two slits (200F) are also formed in the first orthogonal part (32Fa) of the first wiring (32F). Although not illustrated, similarly, two slits (200F) are also formed in the first orthogonal part (34Fa) of the first wiring (34F). In a modified example, one slit (200F) or three or more slits (200F) may be formed in each of the first orthogonal parts (30Fa, 32Fa, 34Fa). Further, in the first wirings (30F, 32F, 34F), no slits are formed in portions other than the first orthogonal parts (30Fa, 32Fa, 34Fa).

As illustrated in FIGS. 4 and 5, two slits (200B) are formed in the second orthogonal part (30Ba) along the orthogonal direction. The slits (200B) are formed over an entire length of the second orthogonal part (30Ba). As illustrated in FIG. 5, the slits (200B) are formed at a depth reaching the second surface (10B) from an upper surface of the second orthogonal part (30Ba). Although not illustrated, similarly, two slits (200B) are also formed in each of the second orthogonal part (32Ba) of the second wiring (32B) and the second orthogonal part (34Ba) of the second wiring (34B).

In a modified example, one slit (200B) or three or more slits (200B) may be formed in each of the second orthogonal parts (30Ba, 32Ba, 34Ba).

Further, in the second wirings (30B, 32B, 34B), no slits are formed in portions other than the second orthogonal parts (30Ba, 32Ba, 34Ba).

The slits (200F, 200B) may be formed along the orthogonal direction in either the first orthogonal parts (30Fa, 32Fa, 34Fa) or the second orthogonal parts (30Ba, 32Ba, 34Ba) or may be formed along the orthogonal direction in both the first orthogonal parts (30Fa, 32Fa, 34Fa) and the second orthogonal parts (30Ba, 32Ba, 34Ba).

FIG. 6 is a perspective view schematically illustrating a motor coil substrate 50 formed using the coil substrate 2 of the embodiment (FIGS. 1-5).

As illustrated in FIG. 6, a substantially cylindrical motor coil substrate 50 is formed by winding the coil substrate 2 of the embodiment (FIGS. 1-5) multiple turns in a circumferential direction about an axis extending in the orthogonal direction (axis extending parallel to the first side (E1) with the first side (E1) (FIG. 1) as a starting point. When the coil substrate 2 is wound, the first surface (10F) of the flexible substrate 10 is positioned on the inner peripheral side, and the second surface (10B) is positioned on the outer peripheral side.

As described above, in the coil substrate 2 of the embodiment, two slits (200F) are formed along the orthogonal direction in each of the first orthogonal parts (30Fa, 32Fa, 34Fa).

Two slits (200B) are formed along the orthogonal direction in each of the second orthogonal parts (30Ba, 32Ba, 34Ba). Therefore, when the coil substrate 2 is wound in the circumferential direction, the first orthogonal parts (30Fa, 32Fa, 34Fa) and the second orthogonal parts (30Ba, 32Ba, 34Ba) can bend at positions where the slits (200F, 200B) are formed.
As a result, when the coil substrate 2 is wound in the circumferential direction, the motor coil substrate 50 can be formed into a cylindrical shape with a substantially circular cross section.
More specifically, in the embodiment, the motor coil substrate 50 is formed into a polygonal cylindrical shape with a cross-sectional shape of 48 or more sides (more preferably 120 or more sides) (that is, a substantially cylindrical shape). The number of sides in the cross-sectional shape of the motor coil substrate 50 can vary depending on factors such as a diameter, the number of turns, and the number of coils of the motor coil substrate 50. Even in this case, the cross-sectional shape of the motor coil substrate 50 may be a polygon of 48 sides or more.

FIG. 7 is a cross-sectional view schematically illustrating a motor 100 formed using the motor coil substrate 50 of the embodiment (FIG. 6).

The motor 100 is formed by positioning the motor coil substrate 50 on an inner side of a yoke 60 and positioning a rotation shaft 80 and a magnet 70 fixed to the rotation shaft 80 on an inner side of the motor coil substrate 50.
As described above, the motor coil substrate 50 of the embodiment is formed into a substantially cylindrical shape (a polygonal shape with a cross-sectional shape of 48 or more sides). Therefore, when the motor 100 is formed, interference between the magnet 70, which is positioned on the inner side of the motor coil substrate 50, and the motor coil substrate 50 is prevented. Further, since a gap between the motor coil substrate 50 and the yoke 60 becomes constant, high heat dissipation performance is achieved. Therefore, when the motor 100 is formed using the coil substrate 2 of the embodiment, a motor 100 with stable performance can be obtained. The first side (E1) is an example of a “reference side.” The first orthogonal parts (30Fa, 32Fa, 34Fa) and the second orthogonal parts (30Ba, 32Ba, 34Ba) are examples of “orthogonal parts.”

### First Alternative Example

In the coil substrate 2 of a first alternative example of the embodiment, the slits (200F) are formed in the first orthogonal parts (30Fa, 32Fa, 34Fa) only, and no slits are formed in the second orthogonal parts (30Ba, 32Ba, 34Ba).

### Second Alternative Example

In the coil substrate 2 of a second alternative example of the embodiment, the slits (200B) are formed in the second orthogonal parts (30Ba, 32Ba, 34Ba) only, and no slits are formed in the first orthogonal parts (30Fa, 32Fa, 34Fa).

### Third Alternative Example

In the coil substrate 2 of a third alternative example of the embodiment, slits similar to the slits (200F) of the first orthogonal parts (30Fa, 32Fa, 34Fa) are also formed in portions other than the first orthogonal parts (30Fa, 32Fa, 34Fa) of the first wirings (30F, 32F, 34F). Similarly, slits similar to the slits (200B) of the second orthogonal parts (30Ba, 32Ba, 34Ba) are also formed in portions other than the second orthogonal parts (30Ba, 32Ba, 34Ba) of the second wirings (30B, 32B, 34B).

### Fourth Alternative Example

In the coil substrate 2 of a fourth alternative example of the embodiment, in a cross section of the first orthogonal parts (30Fa, 32Fa, 34Fa), the flexible substrate 10 and the second orthogonal parts (30Ba, 32Ba, 34Ba), the first orthogonal parts (30Fa, 32Fa, 34Fa) and the second orthogonal parts (30Ba, 32Ba, 34Ba) do not overlap.

### First Modified Example

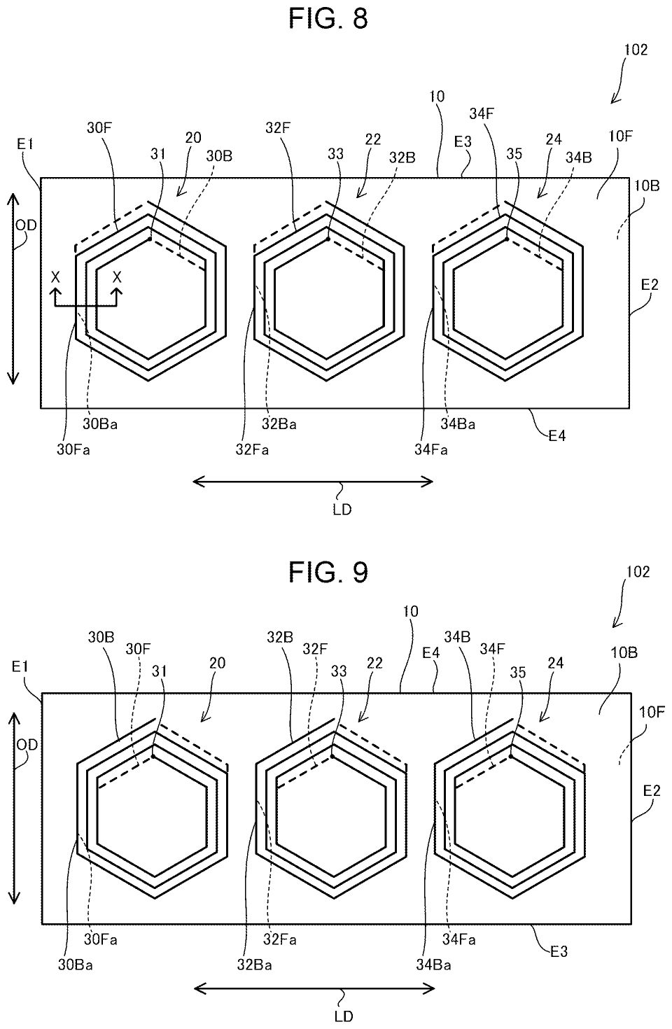

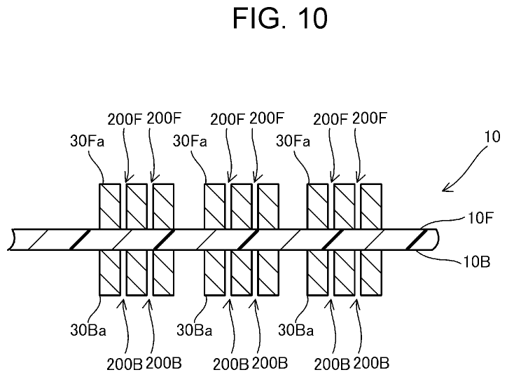

FIGS. 8-10 illustrate a first modified example of the embodiment. In the first modified example, the arrangement of the wirings forming the coils (20, 22, 24) is different from that in the embodiment. FIG. 8 is a plan view illustrating a coil substrate 102 of the first modified example. FIG. 9 is a bottom view illustrating the coil substrate 102 of the first modified example. FIG. 10 is a cross-sectional view between X-X of FIG. 8.

The coil 20 is formed of a coil-shaped first wiring (30F) (FIG. 8) provided on the first surface (10F) and a coil-shaped second wiring (30B) (FIG. 9) provided on the second surface (10B). The first wiring (30F) and the second wiring (30B) are electrically connected via a via conductor 31 penetrating the flexible substrate 10. Similarly, the coil 22 is formed of a first wiring (32F) and a second wiring (32B). The first wiring (32F) and the second wiring (32B) are electrically connected via a via conductor 33. The coil 24 is formed of a first wiring (34F) and a second wiring (34B). The first wiring (34F) and the second wiring (34B) are electrically connected via a via conductor 35.

As illustrated in FIG. 8, the first wiring (30F) is formed in a clockwise spiral shape (hexagonal spiral shape) from an outer periphery toward an inner periphery. The via conductor 31 is formed at an inner peripheral side end of the first wiring (30F). As illustrated in FIG. 9, the second wiring (30B) is formed in a counterclockwise spiral shape (hexagonal spiral shape) from an outer periphery toward an inner periphery. The via conductor 31 is formed at an inner peripheral side end of the second wiring (30B). The first wiring (30F) and the second wiring (30B) are formed in spiral shapes wound in the same direction when viewed from the same surface. The first wiring (30F) and the second wiring (30B) are electrically connected in series and function as one coil 20.

The first wiring (32F) and the second wiring (32B), as well as the first wiring (34F) and the second wiring (34B), have the same relationship as the first wiring (30F) and the second wiring (30B) described above. The first wiring (32F) and the second wiring (32B) are formed in spiral shapes wound in the same direction when viewed from the same surface. The first wiring (32F) and the second wiring (32B) are electrically connected in series and function as one coil 22. The first wiring (34F) and the second wiring (34B) are formed in spiral shapes wound in the same direction when viewed from the same surface. The first wiring (34F) and the second wiring (34B) are electrically connected in series and function as one coil 24.

As illustrated in FIGS. 8 and 9, also in the first modified example, the first wirings (30F, 32F, 34F) have first orthogonal parts (30Fa, 32Fa, 34Fa) extending along the orthogonal direction (see the arrow (OD)). The second wirings (30B, 32B, 34B) also have second orthogonal parts (30Ba, 32Ba, 34Ba) extending along the orthogonal direction (see the arrow (OD)). The first orthogonal part (30Fa) overlaps with the second orthogonal part (30Ba) (see FIG. 10). The first orthogonal part (32Fa) overlaps with the second orthogonal part (32Ba). The first orthogonal part (34Fa) overlaps with the second orthogonal part (34Ba).

Further, although not illustrated, the first surface (10F) and the first wirings (30F, 32F, 34F) are covered with a resin insulation layer. Similarly, the second surface (10B) and the second wirings (30B, 32B, 34B) are covered with a resin insulation layer.

As illustrated in FIG. 10, two slits (200F) are formed in the first orthogonal part (30Fa) along the orthogonal direction. The slits (200F) are formed over an entire length of the first orthogonal part (30Fa). The slits (200F) are formed at a depth reaching the first surface (10F) from an upper surface of the first orthogonal part (30Fa). Although not illustrated, similarly, two slits (200F) are also formed in each of the first orthogonal part (32Fa) of the first wiring (32F) and the first orthogonal part (34Fa) of the first wiring (34F). In a modified example, one slit (200F) or three or more slits (200F) may be formed in each of the first orthogonal parts (30Fa, 32Fa, 34Fa). Further, in the first wirings (30F, 32F, 34F), no slits are formed in portions other than the first orthogonal parts (30Fa, 32Fa, 34Fa).

As illustrated in FIG. 10, two slits (200B) are formed in the second orthogonal part (30Ba) along the orthogonal direction. The slits (200B) are formed over an entire length of the second orthogonal part (30Ba). The slits (200B) are formed at a depth reaching the second surface (10B) from an upper surface of the second orthogonal part (30Ba). Although not illustrated, similarly, two slits (200B) are also formed in each of the second orthogonal part (32Ba) of the second wiring (32B) and the second orthogonal part (34Ba) of the second wiring (34B). In a modified example, one slit (200B) or three or more slits (200B) may be formed in each of the second orthogonal parts (30Ba, 32Ba, 34Ba). Further, in the second wirings (30B, 32B, 34B), no slits are formed in portions other than the second orthogonal parts (30Ba, 32Ba, 34Ba).

Also in the case where the motor coil substrate 50 is formed using the coil substrate 102 of the first modified example (FIGS. 8-10), the motor coil substrate 50 can be formed into a cylindrical shape with a substantially circular cross section. More specifically, the motor coil substrate 50 is formed into a polygonal cylindrical shape with a cross-sectional shape of 48 or more sides (more preferably 120 or more sides) (that is, a substantially cylindrical shape). When the motor 100 is formed, interference between the magnet 70 and the motor coil substrate 50 is prevented. Further, high heat dissipation performance is achieved. Therefore, also in the case where the motor 100 is formed using the coil substrate 102 of the first modified example, a motor 100 with stable performance can be obtained.

### First Alternative Example

In the coil substrate 102 of a first alternative example of the first modified example, the slits (200F) are formed in the first orthogonal parts (30Fa, 32Fa, 34Fa) only, and no slits are formed in the second orthogonal parts (30Ba, 32Ba, 34Ba).

### Second Alternative Example

In the coil substrate 102 of a second alternative example of the first modified example, the slits (200B) are formed in the second orthogonal parts (30Ba, 32Ba, 34Ba) only, and no slits are formed in the first orthogonal parts (30Fa, 32Fa, 34Fa).

### Third Alternative Example

In the coil substrate 2 of a third alternative example of the first modified example, slits similar to the slits (200F) of the first orthogonal parts (30Fa, 32Fa, 34Fa) are also formed in portions other than the first orthogonal parts (30Fa, 32Fa, 34Fa) of the first wirings (30F, 32F, 34F). Similarly, slits similar to the slits (200B) of the second orthogonal parts (30Ba, 32Ba, 34Ba) are also formed in portions other than the second orthogonal parts (30Ba, 32Ba, 34Ba) of the second wirings (30B, 32B, 34B).

### Fourth Alternative Example

In a coil substrate 102 of a fourth alternative example of the first modified example, the first wirings (30F, 32F, 34F) and the second wirings (30B, 32B, 34B) are formed such that they do not overlap via the flexible substrate 10. In the fourth alternative example, in a cross section of the first orthogonal parts (30Fa, 32Fa, 34Fa), the flexible substrate 10 and the second orthogonal parts (30Ba, 32Ba, 34Ba), the first orthogonal parts (30Fa, 32Fa, 34Fa) and the second orthogonal parts (30Ba, 32Ba, 34Ba) do not overlap.

Japanese Patent Application Laid-Open Publication No. 2020-61532 describes a coil substrate having a flexible substrate and spiral-shaped wirings formed on both sides of the flexible substrate. A motor coil substrate is formed by winding the coil substrate into a cylindrical shape. A motor is formed by positioning the formed motor coil substrate on an inner side of a cylindrical yoke and positioning a rotation shaft and a magnet on an inner side of the motor coil substrate.

In Japanese Patent Application Laid-Open Publication No. 2020-61532, it is thought that the coil substrate is wound in a circumferential direction about an axis extending in an orthogonal direction (width direction) orthogonal to a longitudinal direction of the flexible substrate with a side on one end in the longitudinal direction as a starting point. The side described above also extends along the orthogonal direction. In order to improve motor performance, orthogonal parts extending along the orthogonal direction described above may be provided in the wirings of the coil substrate.

When the orthogonal parts are provided in the wirings, gaps existing between the orthogonal parts also extend along the orthogonal direction. When the coil substrate is wound in the circumferential direction as described above, it is thought that, since there are no wirings in the gaps between the orthogonal parts, a force is likely to be applied thereto and bending is likely to occur. As a result, it is thought that the motor coil substrate may be formed into a polygonal cylindrical shape with a polygonal cross-section (for example, a polygonal cylindrical shape with a cross section of about 4-12 sides) instead of a cylindrical shape with a circular cross section.

When the motor coil substrate has a polygonal cylindrical shape with a cross section of about 4-12 sides, it is thought that the motor coil substrate may interfere with the magnet positioned on the inner side of the motor coil substrate when the motor is formed. Further, since a gap between the motor coil substrate and the yoke is not constant, it is thought that heat dissipation performance may deteriorate. As a result, it is thought that stable motor performance cannot be achieved.

A coil substrate according to an embodiment of the present invention includes: a flexible substrate that has a first surface and a second surface on the opposite side with respect to the first surface; and a coil that is formed by a coil-shaped wiring provided on the first surface and a coil-shaped wiring provided on the second surface. The coil substrate can be formed into a substantially cylindrical shape by being wound in a circumferential direction about an axis extending in an orthogonal direction orthogonal to a longitudinal direction of the flexible substrate with a reference side on one end side in the longitudinal direction as a starting point. The wirings have orthogonal parts extending along the orthogonal direction. The orthogonal parts include a first orthogonal part on the first surface and a second orthogonal part on the second surface. At least one slit is formed along the orthogonal direction in at least one of the first orthogonal part and the second orthogonal part.

In a coil substrate according to an embodiment of the present invention, at least one slit is formed along the orthogonal direction in at least one of the first orthogonal part and the second orthogonal part. When the coil substrate is wound in the circumferential direction, the orthogonal parts can bend at positions where slits are formed. As a result, when the coil substrate is wound in the circumferential direction, the motor coil substrate can be formed into a cylindrical shape with a substantially circular cross section. Therefore, when the motor is formed, interference between the magnet, which is positioned on the inner side of the motor coil substrate, and the motor coil substrate is prevented. Further, since a gap between the motor coil substrate and the yoke becomes constant, high heat dissipation performance is achieved. Therefore, when the motor is formed using the coil substrate of the embodiment, a motor with stable performance can be obtained.

In a coil substrate according to an embodiment of the present invention, at least one slit is formed along the orthogonal direction in one of the first orthogonal part and the second orthogonal part.

In a coil substrate according to an embodiment of the present invention, at least one slit is formed along the orthogonal direction in both the first orthogonal part and the second orthogonal part.

In a coil substrate according to an embodiment of the present invention, the first orthogonal part and the second orthogonal part overlap in a cross section of the first orthogonal part, the flexible substrate, and the second orthogonal part.

A motor coil substrate according to an embodiment of the present invention is formed by winding the above coil substrate according to an embodiment of the present invention into a substantially cylindrical shape. The first surface is positioned on an inner peripheral side, and the second surface is positioned on an outer peripheral side.

In a motor coil substrate according to an embodiment of the present invention, the coil substrate has a polygonal cylindrical shape with a polygonal cross-sectional shape of 48 or more sides.

As described above, a motor coil substrate according to an embodiment of the present invention can be formed into a cylindrical shape with a substantially circular cross section. When a motor is formed, interference between a magnet and the motor coil substrate is prevented. High heat dissipation performance is achieved. Therefore, when a motor is formed using the motor coil substrate of the embodiment, a motor with stable performance can be obtained.

A motor according to an embodiment of the present invention is formed by positioning the above motor coil substrate according to an embodiment of the present invention on an inner side of a cylindrical yoke and positioning a rotation shaft and a magnet on an inner side of the motor coil substrate.

In a motor according to an embodiment of the present invention, interference between the magnet and the motor coil substrate is prevented. Further, since a gap between the motor coil substrate and the yoke becomes constant, high heat dissipation performance is achieved. A motor with stable performance can be obtained.

Obviously, numerous modifications and variations of the present invention are possible in light of the above teachings. It is therefore to be understood that within the scope of the appended claims, the invention may be practiced otherwise than as specifically described herein.

1. A coil substrate, comprising:
a flexible substrate; and
a coil comprising a first wiring formed on a first surface of the flexible substrate and a second wiring formed on a second surface of the flexible substrate on an opposite side with respect to the first surface,
wherein the flexible substrate is configured to be wound around an axis extending in an orthogonal direction orthogonal to a longitudinal direction of the flexible substrate such that the flexible substrate is formed into a cylindrical shape, and the coil is formed such that the first wiring has a first orthogonal part extending along the orthogonal direction, that the second wiring has a second orthogonal part extending along the orthogonal direction, and that at least one of the first orthogonal part and the second orthogonal part has at least one slit formed along the orthogonal direction.

2. The coil substrate according to claim 1, wherein the coil is formed such that one of the first orthogonal part and the second orthogonal part has the at least one slit formed therein.

3. The coil substrate according to claim 1, wherein the coil is formed such that each of the first orthogonal part and the second orthogonal part has the at least one slit formed therein.

4. The coil substrate according to claim 1, wherein the coil is formed such that the first orthogonal part and the second orthogonal part overlap in a cross section of the first orthogonal part, the flexible substrate, and the second orthogonal part.

5. The coil substrate according to claim 2, wherein the coil is formed such that the first orthogonal part and the second orthogonal part overlap in a cross section of the first orthogonal part, the flexible substrate, and the second orthogonal part.

6. The coil substrate according to claim 3, wherein the coil is formed such that the first orthogonal part and the second orthogonal part overlap in a cross section of the first orthogonal part, the flexible substrate, and the second orthogonal part.

7. The coil substrate according to claim 1, wherein the coil is formed in a plurality such that the plurality of coils is formed on the flexible substrate, and each of the coils is formed such that the first wiring has a first orthogonal part extending along the orthogonal direction, that the second wiring has a second orthogonal part extending along the orthogonal direction, and that at least one of the first orthogonal part and the second orthogonal part has at least one slit formed along the orthogonal direction.

8. The coil substrate according to claim 7, wherein each of the coils is formed such that one of the first orthogonal part and the second orthogonal part has the at least one slit formed therein.

9. The coil substrate according to claim 7, wherein each of the coils is formed such that each of the first orthogonal part and the second orthogonal part has the at least one slit formed therein.

10. The coil substrate according to claim 7, wherein each of the coils is formed such that the first orthogonal part and the second orthogonal part overlap in a cross section of the first orthogonal part, the flexible substrate, and the second orthogonal part.

11. The coil substrate according to claim 8, wherein each of the coils is formed such that the first orthogonal part and the second orthogonal part overlap in a cross section of the first orthogonal part, the flexible substrate, and the second orthogonal part.

12. The coil substrate according to claim 9, wherein each of the coils is formed such that the first orthogonal part and the second orthogonal part overlap in a cross section of the first orthogonal part, the flexible substrate, and the second orthogonal part.

13. A motor coil substrate, comprising:
the coil substrate of claim 1 wound into the cylindrical shape such that the first surface of the flexible substrate is positioned on an inner peripheral side of the cylindrical shape and that the second surface is of the flexible substrate is positioned on an outer peripheral side of the cylindrical shape.

14. The motor coil substrate according to claim 13, wherein the coil substrate of claim 1 is wound into the cylindrical shape such that the coil substrate has a polygonal cylindrical shape with a polygonal cross-sectional shape of 48 or more sides.

15. A motor coil substrate, comprising:
the coil substrate of claim 2 wound into the cylindrical shape such that the first surface of the flexible substrate is positioned on an inner peripheral side of the cylindrical shape and that the second surface is of the flexible substrate is positioned on an outer peripheral side of the cylindrical shape.

16. A motor coil substrate, comprising:
the coil substrate of claim 3 wound into the cylindrical shape such that the first surface of the flexible substrate is positioned on an inner peripheral side of the cylindrical shape and that the second surface is of the flexible substrate is positioned on an outer peripheral side of the cylindrical shape.

17. A motor coil substrate, comprising:
the coil substrate of claim 4 wound into the cylindrical shape such that the first surface of the flexible substrate is positioned on an inner peripheral side of the cylindrical shape and that the second surface is of the flexible substrate is positioned on an outer peripheral side of the cylindrical shape.

18. A motor coil substrate, comprising:
the coil substrate of claim 7 wound into the cylindrical shape such that the first surface of the flexible substrate is positioned on an inner peripheral side of the cylindrical shape and that the second surface is of the flexible substrate is positioned on an outer peripheral side of the cylindrical shape.

19. A motor, comprising:
a cylindrical yoke;
the motor coil substrate of claim 13 positioned on an inner side of the cylindrical yoke;
a rotation shaft positioned on the inner side of the cylindrical yoke such that the rotation shaft is positioned on an inner side of the motor coil substrate; and
a magnet fixed to the rotation shaft positioned on the inner side of the cylindrical yoke such that the magnet is positioned on the inner side of the motor coil substrate.

20. A motor, comprising:
a cylindrical yoke;
the motor coil substrate of claim 14 positioned on an inner side of the cylindrical yoke;
a rotation shaft positioned on the inner side of the cylindrical yoke such that the rotation shaft is positioned on an inner side of the motor coil substrate; and
a magnet fixed to the rotation shaft positioned on the inner side of the cylindrical yoke such that the magnet is positioned on the inner side of the motor coil substrate.
